(19) United States
(12) Patent Application Publication
(10) Pub. No.: US 2018/0240925 A1
(43) Pub. Date: Aug. 23, 2018

(54) COMPOSITE SYSTEM FOR THE BACK CONTACTING OF PHOTOVOLTAIC MODULES

(71) Applicant: Eppstein Technologies GmbH, 65817 Eppstein (DE)

(72) Inventors: MARKUS REES, 65817 Eppstein (DE); MEISER VALENCIA, 65207 Wiesbaden (DE)

(73) Assignee: Eppstein Technologies GmbH, 65817 Eppstein (DE)

(21) Appl. No.: 15/752,165

(22) PCT Filed: Aug. 2, 2016
(86) PCT No.: PCT/EP2016/068429

§ 371 Date: Feb. 12, 2018

(30) Foreign Application Priority Data
Aug. 12, 2015 (DE) 10 2015 113 297.4

(51) Int. Cl. H01L 31/05; B32B 17/10; B32B 15/08

(52) U.S. Cl. CPC H01L 31/0516; B32B 15/08; B32B 17/10018

(57) ABSTRACT

A composite system for the back contacting of photovoltaic modules includes a metal foil, which has a conducting-path structure, and at least one electrically insulating and stabilizing polymer layer, which is applied to the metal foil and adhesively connected to the metal foil. The main task of the stabilizing polymer layer is to mechanically stabilize the structured conducting paths such that the structured conducting paths do not move when shear forces occur, which are triggered, for example, by elevated temperature during the lamination process or during operation.

The present invention relates to a composite system for the back contacting of photovoltaic modules, including a metal foil having a conductor track structure and at least one electrically insulating and stabilizing polymer layer which is applied to and adhesively connected to the metal foil.

In a photovoltaic module (PV module) materials (glass, cellular silicone, metal, embedding materials consisting of plastic layers) are combined that have different thermomechanical properties such as coefficient of thermal expansion and coefficient of elasticity.

Usually, the PV modules are produced in a vacuum lamination process in which the individual plastic layers are joined together under the influence of temperature and pressure. The different thermomechanical properties of the different materials lead to stresses in the module, which results in shearing forces between the individual layers

In the case of back-contacted cells, large-area interconnect structures are often used for interconnecting the cells, since these interconnect structures allow reducing ohmic losses. For example, so-called “conductive backsheets” are known, as for example described in documents EP 2 810 539 A1 or EP 2 618 381 A1. Patent application WO 2011 003969 A2, for example, describes a composite system for PV modules, wherein the composite system consists of a carrier foil, a metal foil applied to the carrier foil, and an insulating layer which is applied to the metal foil and prevents short circuits between the cells and the metal foil. In addition to good electrical insulation values, this insulation layer must also function as a mechanical barrier, which prevents electrically conductive particles or unevennesses of the metallized backside of cell from being pushed through the insulation layer and thus causing short circuits.

A disadvantage of the PV modules known from the prior art is that, depending on the choice of the plastics for the insulating layer or for the carrier layer, if present, the conditions in the vacuum lamination process (in particular elevated temperatures) can lead to excessive softening of the mentioned layers. The forces between the layers resulting from the different coefficients of thermal expansion can then cause the conductor paths in the metal layer to shift relative to each other and even touch each other thereby causing short circuits. Furthermore, the insulation layer may locally lose its barrier properties, which can lead to short circuits between conductor paths and the backsides of the cells.

The aesthetics of the solar modules for example in the area of building integration is increasingly important. One of the most important optical features in the module is color. It would therefore be advantageous to be able to color the insulation layer or conductor path which is visible from the front in the interspaces of the cells.

The object of the present invention was therefore to propose a composite system for the back-contacting of PV modules, which prevents a displacement of the conductor paths in the metal layer and the loss of the barrier function of the insulating layer, so as to avoid short circuits. Another object was to make it possible to produce a PV module which meets the requirements for a desired continuous coloring and in which the insulation layer and the conductor paths no longer differ from each other in color.

For solving the known problems of the prior art the present invention proposes a special composite system for contacting in the manufacture of PV modules.

The composite system according to the invention for back contacting of photovoltaic modules includes a metal foil which has a conductor path structure and at least one electrically insulating and stabilizing polymer layer which is applied to the metal foil and adhesively bonded thereto. The main purpose of the stabilizing polymer layer is to mechanically stabilize the structured conductor paths and to prevent the structured conductor paths from shifting when shear forces occur, for example due to elevated temperature, during the lamination process, or during operation.

According to the invention it is preferred when the composite system additionally includes a polymer composite composed of at least two polymer layers. This polymer composite should on the one hand have sealing properties, i.e., to form an adhesive connection to the photovoltaic cells. In addition, the polymer composite has a barrier function and enables electrical insulation of the composite system.

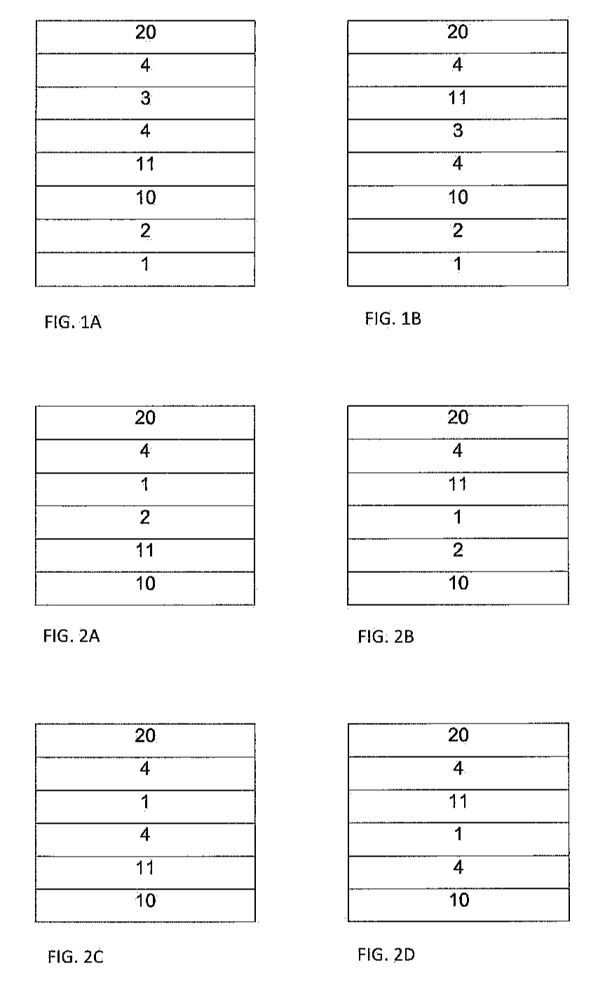

In a preferred embodiment (Bottom-Up system, FIG. 1), this stabilizing polymer layer is arranged behind the metal foil (conductor layer) (Bottom) and supplemented by a further polymer composite (Up), which is arranged between the conductor layer and the cells, adhesively bonds the cells to each other by means of sealing layers, ensures electrical insulation between the conductor layer and the cells and by means of a barrier layer ensures the mechanical barrier function which prevents conductive particles or inhomogeneities of the conductive backside of cell from being pushed through. Specifically, this barrier function is useful in the case of uneven backsides of metal wrap through (MWT) cells.

In a further preferred embodiment (Up-system, FIG. 2), the stabilizing polymer layer is part of the polymer composite, which is applied directly to the metal foil. In addition to stabilizing the conductor paths, the polymer composite also ensures electrical insulation against the cell and provides the barrier function.

The main tasks of the electrically insulating polymer layers of the polymer composite are to mechanically protect the structured conductor paths against temperature influences.

The flow behavior and the thermal properties of the polymer layers used for this purpose ensure the mechanical stability of the conductor paths during temperature changes during production of the PV module or during operation and prevent localized loss of the mechanical barrier function, so as to avoid short circuits.

The electrical contact between the cell terminals and the conductor path is ensured by openings in the respective polymer composites, with a bonding means being applied in the openings for this purpose.

The openings are introduced by a thermo-mechanical process, chemically or by a laser process. Hereby, it must be ensured that the polymer composites are compatible with the manufacturing processes.

It is also important that the different components of the composite system are compatible with the different module materials, such as: encapsulation, glass, conductive adhesive, solders and solar cells. Furthermore, these components should meet the requirements of the overall long-term stability of the module.

The polymer layers to be used for mechanical stabilization and/or to ensure the mechanical barrier function must not undergo excessive softening at the temperatures occurring during lamination or during operation. For this the polymer layers have softening temperatures which are outside the lamination temperature window. Polymers with glass transition temperatures outside this lamination window are particularly advantageous. Furthermore, the polymers should have the lowest possible water absorption, since in some polymers moisture acts as a plasticizer.

The stabilizing polymer layer used for mechanical stabilization or as mechanical barrier preferably consists of at least one of the following polymers: polyesters, polyamides, polyimides, cellulose acetates, polyoxymethylenes, polyvinyl chlorides, polystyrene, polyether ketones, polyepoxides, polyacrylates, polyacrylonitriles, polyurethanes and their halogenated derivatives or modified polymers.

Another optional polymer layer capable of functioning as a barrier preferably consists of at least one of the following polymers: modified polysiloxanes, epoxy resins, polycarbonates, polyamides, polyacrylates, polyacrylonitriles, polymethyl methacrylates or polyesters, their halogenated derivatives and modified polymers.

Further polymer layers, which are used as sealing layers, preferably consist of at least one of the following polymers: polyethylene vinyl acetates, polyvinyl butyrals, polystyrene, polyvinyl chlorides or thermoplastic polyolefins, their derivatives or modified polymers.

In a preferred embodiment, the sealing polymer layer has a softening temperature of greater than 150° C., and has no glass transition between 50° C. and 150° C., preferably no glass transition between 50° C. and 120° C., and the elastic portion of the sealing Polymer layer is greater than the plastic content in the temperature range from 50° C. to 150° C.

According to the invention it is preferred when a polymer layer which contacts the metal foil directly, is formed as an adhesive layer and is preferably crosslinkable and has no glass transition temperature between 50° C. and 150° C.

In an advantageous embodiment of the present invention, a polymer layer is formed as an adhesive layer and includes at least one of the following polymers: epoxy resins, polyacrylates, modified polysiloxanes, polyvinyl butyrals or crosslinking polyethylene vinyl acetates, polyepoxides or polyurethanes.

The metal foil is preferably made of copper. It is also possible to use aluminum, tin or a tin alloy, or a plated tin foil or silver. In a further advantageous embodiment, the metal foil has a thickness of at least 5 μm, preferably 5-60 μm and particularly preferably 10-40 μm.

The typical construction of a foil system according to the first embodiment (Bottom-Up) of the present invention is shown in FIG. 1. Hereby, FIG. 1a shows a typical construction with a coloring of a metal foil and FIG. 1b shows such a construction in which the plastic foil is colored.

Hereby, a stabilizing polymer layer (Bottom) is used to enable mechanical stability of the conductor path structure. Bonding of the polymer layer to the conductor path is realized with a boding means. The bonding means is preferably an adhesive.

The adhesive used is a crosslinkable adhesive and as a result gives the foil system mechanical strength. The mechanically stabilizing and temperature-activated bonding means prevents deformation of the foil system which may be caused by shear forces generated in the lamination process and, accordingly, a displacement of the conductor paths relative to each other. The present invention thus enables preventing short circuits that may result from such a displacement.

The adhesive layer according to the invention is preferably at least one of the following polymers: epoxy resins, polyacrylates, modified polysiloxanes, polyvinyl butyrals or crosslinking polyethylene vinyl acetates, polyepoxides or polyurethanes.

Another advantage of the proposed composite system is the possibility of coloring, so that the insulation layer or the conductor paths that are visible from the front in the cell interspaces no longer stand out in color from the module. The coloring can be applied to the conductor track or introduced in the polymer layer composite, which acts as an insulating layer and mechanical barrier (Up). The coloring can be accomplished by lamination, sputtering, evaporation, sol-gel processes, printing, enameling or spraying.

When coloring the conductor paths, polymer matrices (preferably one polymer matrix) are used, which also act as a barrier or electrically insulating layer. Inorganic pigments are one of the major constituents of the colors and are typically embedded in a polymer matrix or applied to the polymer matrix.

The described coloring of the conductor path has the further advantage to additionally act as electrical insulation and/or mechanical barrier.

The present Bottom-Up composite system enables decoupling of the stabilizing function (Bottom) and the mechanical barrier (Up) and the composite system can be manufactured in two components. This functional decoupling allows high flexibility in the production of the composite system according to the invention according to the present invention. In a further advantageous embodiment, the stabilizing polymer layer and the barrier-capable polymer layer are therefore located in two independent foil composites.

The present invention thus also includes a process for producing a composite system for the back contacting of photovoltaic modules, in which production of the individual foil composites takes place separately.

Another advantage of the composite system according to the invention is realized in the production of PV modules. Namely, it is known that curling of the metal-polymer layer composite systems during manufacture of solar modules by back contacting makes it difficult to apply the cells during module production. This phenomenon is related to the different coefficients of expansion between the polymer layers and the conductor paths. With the composite system according to the invention, this disadvantageous effect is avoided.

In a further preferred embodiment (Up-system) the stabilizing function for the conductor paths, the electrical insulation between cells and conductor paths and the mechanical barrier function are combined in a polymer composite which is adhesively bonded to the conductor layer and during lamination forms an adhesive connection with the backsides of the cells.

Two exemplary embodiments are shown in FIG. 2, wherein FIGS. 2a and 2b represent two-foil composites and FIGS. 2c and 2d show triple-foil composites.

In the case of the two-foil composite, the polymer composite consists of two different polymer layers and one adhesive layer. The triple polymer composite consists of at least two different polymer layers.

In the two-foil composite according to FIGS. 2a and 2b, the polymer layer arranged directly above the conductor path is designed as a mechanically stabilizing, electrically insulating layer with a mechanical barrier function. The bonding of these polymer layers on the metal foil is realized by means of a bonding means. The bonding means is preferably an adhesive.

The adhesive used is a crosslinkable adhesive and thus gives the foil system consisting of polymer composite and conductor layer mechanical strength. The adhesive layer according to the invention is preferably at least one of the following polymers: epoxy resins, polyacrylates, modified polysiloxanes, polyvinyl butyrals or crosslinking polyethylene vinyl acetates, polyepoxides or polyurethanes.

The polymer layer oriented towards the cell is configured as an adhesive layer and during lamination connects the foil system to the cells.

The polymer layer serving for insulation, mechanical stabilization and mechanical barrier formation has a softening temperature and, particularly advantageously, also glass transition temperatures which lie outside the lamination temperature window and optimally does not absorb water. It preferably consists of at least one of the following polymers: polyesters, polyamides, polyimides, cellulose acetates, polyoxymethylenes, polyvinyl chlorides, polystyrene, polyether ketones, polyepoxides, polyacrylates, polyacrylonitriles, polyurethanes and their halogenated derivatives or modified polymers.

In the triple-foil composite according to FIGS. 2c and 2d, the stabilizing polymer layer is connected by way of an adhesive polymer (consisting of at least one of the following polymers: polyethylene vinyl acetates, polyvinyl butyrals, polystyrene, polyvinyl chlorides or thermoplastic polyolefins, their derivatives or modified polymers) with the conductor layer, whose rheological properties such as dynamic viscosity, loss modulus, storage modulus, glass transition temperature are specifically selected so that the stabilizing property is maintained during the Vacuum lamination process during module production.

Furthermore, the two-foil and triple-foil composites should especially be chemically compatible with encapsulation, glass, conductive adhesive and solar cells. In addition, the polymer layers must meet the requirements for long-term stability of solar modules. In particular, the stresses on the backside of the cell and/or the contacts during temperature change have to be taken into account.

In this second embodiment it is also possible to color the polymer layers. However, this must be compatible with the manufacturing process of back-contacted solar cells.

### LIST OF REFERENCE NUMERALS

1 Stabilizing polymer layer (polyesters, polyamides, polyimides, cellulose acetates, polyoxymethylenes, polyvinyl chlorides, polystyrene, polyether ketones, polyepoxides, polyacrylates, polyacrylonitriles, polyurethanes and their halogenated derivatives, modified polymers)
2 Adhesive layer (epoxy resins, polyacrylates, modified polysiloxanes, polyvinyl butyrals, crosslinking polyethylene vinyl acetates, polyepoxides, polyurethanes)
3 Polymer layer (polyacrylates, modified polysiloxanes, epoxy resins, polycarbonates, polyamides, polyacrylates, polyacrylonitriles, polymethylmethacrylates, polyesters and their halogenated derivatives, modified polymers)
4 Polymer layer (polyethylene vinyl acetates, polyvinyl butyrals, polystyrene, polyvinyl chlorides, thermoplastic polyolefins or their derivatives, modified polymers)
10 Metal foil (Cu, Al, Ag, Sn)
11 Coloring
20 Photovoltaic cells

1. A composite system for back contacting of photovoltaic modules, comprising:
a metal foil having a conductor path structure, and
at least one electrically insulating and stabilizing polymer layer applied to the metal foil and adhesively bonded thereto.

2. The composite system of claim 1, further comprising a polymer composite composed of at least two different polymer layers.

3. The composite system of claim 1, characterized in that the stabilizing polymer layer is mounted behind the metal foil and the polymer composite consisting of at least three polymer layers is applied to the metal foil.

4. The composite system of claim 1, characterized in that the stabilizing polymer layer is part of the polymer composite, which is applied directly over the metal foil and at the same time constitutes a thermomechanical barrier.

5. The composite system of claim 1, characterized in that
the stabilizing polymer layer consists of at least one of the following polymers: polyesters, polyamides, polyimides, cellulose acetates, polyoxymethylenes, polyvinyl chlorides, polystyrene, polyether ketones, polyepoxides, polyacrylates, polyacrylonitriles, polyurethanes and their halogenated derivatives or modified polymers and/or
a sealant polymer layer consists of at least one of the following polymers: polyethylene vinyl acetates, polyvinyl butyrals, polystyrene, polyvinyl chlorides or thermoplastic polyolefins, their derivatives or modified polymers.

6. The composite system of claim 1, characterized in that a barrier-capable polymer layer consists of at least one of the following polymers: polyacrylates, modified polysiloxanes, epoxy resins, polycarbonates, polyamides, polyacrylates, polyacrylonitriles, polymethyl methacrylates or polyesters, their halogenated derivatives and modified polymers.

7. The composite system of claim 1, characterized in that
the sealing polymer layer has a softening temperature of greater than 150° C., and the sealing polymer layer has no glass transition between 50° C. and 150° C., preferably no glass transition between 50° C. and 120° C., and
the elastic portion of the sealing polymer layer is greater than the plastic portion in the temperature range of 50° C. to 150° C.

8. The composite system of claim 1, characterized in that a polymer layer, which directly contacts the metal foil, is configured as an adhesive layer and is preferably crosslinkable and has no glass transition temperate between 50° C. to 150° C.

9. The composite system of claim 1, characterized in that the adhesive layer consists of at least one of the following polymers: epoxy resins, polyacrylates, modified polysiloxanes, polyvinyl butyrals or crosslinking polyethylene vinyl acetates, polyepoxides or polyurethanes.

10. The composite system of claim 1, characterized in that the composite system contains in one layer inorganic pigments within or above a polymer matrix.

11. The composite system of claim 1, characterized in that the metal foil consists of copper, aluminum or silver, or tin or a tin alloy, or a plated tin foil.

12. The composite system of claim 1, characterized in that the metal foil has a thickness of more than 5 microns, preferably 5-60 μm, and more preferably 10-40 μm.

13. The composite system of claim 1, characterized in that the stabilizing polymer layer and the barrier-containing polymer layer are located in two independent film composites.

14. A method for producing the composite system of claim 13, characterized in that the production of the individual film composites takes place separately.
